(19) United States
(12) Patent Application Publication
(10) Pub. No.: US 2025/0297979 A1
(43) Pub. Date: Sep. 25, 2025

(54) TEST SYSTEM FOR IONIC CONTAMINATION

(71) Applicant: Raytheon Company, Tewksbury, MA (US)

(72) Inventors: Mark R. Northrup, Marana, AZ (US); Lynn J. Rozanski, Tucson, AZ (US); Kyle R. Ladera, Tucson, AZ (US)

(21) Appl. No.: 18/614,080

(22) Filed: Mar. 22, 2024

(51) Int. Cl. G01N 27/07; G01N 30/96

(52) U.S. Cl. CPC G01N 27/07; G01N 30/96

(57) ABSTRACT

A snorkel for determining the presence of contaminants and electrical properties of a component on a PCB is provided. The snorkel includes a housing having a plurality of ribs that are each configured to move between a first position and a second position, a fluid inlet port, and a fluid outlet port. The snorkel also has a first flexible seal that defines a fluid boundary and a second flexible seal that defines a vacuum boundary. The fluid inlet/outlet ports define a fluid channel within the fluid boundary. The first flexible seal is within the vacuum boundary such that the fluid boundary is disposed within the vacuum boundary. The snorkel also has a plurality of electrical probes that can employ a four-point probe method where a tip of each electrical probe of the plurality of probes is disposed within the fluid channel.

### TECHNICAL FIELD

Examples relate to a system for testing components on a printed circuit board (PCB) and more specifically to a system that detects the presence of contaminants at components and a PCB and the electrical characteristics of components on a PCB.

### BACKGROUND

In order to ensure that PCBs provide their intended function, an environment on the PCB needs to be clean and components on the PCB need to have proper electrical characteristics. If ionics are present on the PCB, this can cause the formation and propagation of dissolution, depletion, migration, or deposition of conductive ions forming a resistive path (e.g., metal spider web, fern-like structures, dendrites, flux islands, etc.) on the PCB. If any of these form on the PCB, this can adversely impact the performance of components on the PCB and lead to premature failure. In the case of dendrites, they have conductive materials that branch out across a surface of the PCB. Eventually, dendrites bridge two or more conductive elements. This bridging can cause short-circuiting and failure.

### BRIEF DESCRIPTION OF DRAWINGS

FIG. 1 illustrates a system for determining the presence of contaminants along with the electrical properties of a PCB.

FIG. 2A shows a snorkel of the system of FIG. 1.

FIG. 2B shows flexible fluid and vacuum seals of the snorkel of FIG. 2A.

FIGS. 3 and 4 show the snorkel of FIG. 2A in expanded and contracted configurations.

FIG. 5 illustrates an alternative embodiment of a snorkel that can be used with the system in FIG. 1.

### DETAILED DESCRIPTION

The following description and the drawings sufficiently illustrate teachings to enable those skilled in the art to practice them. Other embodiments may incorporate structural, logical, electrical, process, and other changes. Portions and features of some examples may be included in, or substituted for, those of other examples. Teachings set forth in the claims encompass all available equivalents of those claims. Any discussion of a feature in the singular can be equivalent to discussion of feature in the plural. Thus, the discussion of a feature in the singular such as “element” can also be applicable to the feature in the plural, such as “elements.” Similarly, the discussion of a feature in the plural such as “elements” can also be applicable to the feature in the plural, such as “elements.”

Examples address the problems noted above by providing a system that can test a cleanliness along with electrical characteristics of individual components on a PCB. The system can be used to detect the presence of ionics at and underneath a component and between the component and a PCB. The system can include an arm and a snorkel at a distal end of the arm. The snorkel can have a flexible fluid seal and a flexible vacuum seal.

The snorkel can also have ribs that can define a flexible housing. The flexible vacuum seal and the flexible fluid seal can couple with the ribs. The ribs can move between a first position and a second position. By virtue of moving between the first position and the second position, the flexible housing and in turn the snorkel, can be adjusted to fit around components having different sizes. Each of the flexible fluid seal and flexible vacuum seal can be adjusted and placed around a component on a PCB. Each of the flexible fluid seal and the flexible vacuum seal can expand and can contract with the ribs of the flexible housing and in turn can expand and can contract with the flexible housing. The system can have a vacuum port that extends to the snorkel and, in conjunction with the flexible vacuum seal, can create a vacuum around the component when the system is at the snorkel thereby securing the snorkel to the PCB.

The system can also include a fluid input and a fluid outlet. Each of the fluid input and the fluid output can respectively extend to a fluid inlet port at the snorkel and a fluid outlet at the snorkel. The snorkel can define a fluid channel around the component at the PCB where the fluid input port can provide fluid to the fluid channel and the fluid output port can be used to pump the fluid out of the fluid channel.

The snorkel can have electrodes. When fluid is provided to the fluid channel, a resistance across the electrodes can be measured to determine the presence of ionics in the fluid when a voltage is applied to the electrodes. In addition, when ionics are detected in the fluid, fluid evacuated from the channel can be tested to determine a type of ionic present in the fluid and a concentration of the ionic. The presence of the ionic in the fluid can correspond to the presence of contaminants and a cleanliness of the component.

Furthermore, the electrodes can be adjustable based on the dimensions of individual components being tested in order to determine electrical characteristics of individual components. Here, the electrodes can implement a four-point probe method, which can provide for adjustability to account for different component dimensions. Electrical resistance that correlates to the dimensions can be used to determine performance of individual components. Performance of individual components can be tied to overall performance of an integrated circuit having the individual components. The four-point probe method can involve placing four electrical contacts onto the surface of the material in a square configuration and measuring the voltage difference between the inner two contacts while passing a known current through the outer two contacts. The resistivity can then be calculated using the dimensions of the probe and the measured values (e.g., varying X-Y dimensions inner and outer contacts).

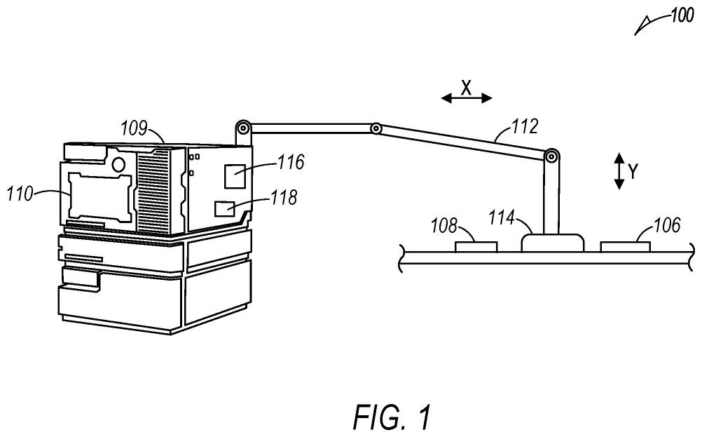

Now making reference to the Figures, FIG. 1 illustrates a test system 100 for determining the presence of contaminants along with the electrical properties of a PCB 102. The contaminants can be ionics, which can be disposed on the PCB 102. For purposes of discussion herein, the PCB 102 along with components 104-108 disposed on the PCB 102 are exaggerated throughout the Figures. The test system 100 can be a component isolation sampler, which can be used to identify a contaminant type and a concentration of contaminants on the PCB 102 and at the components 104-108. The test system 100 can also be used to determine electrical characteristics of the PCB 102 and the components 104-108.

The test system 100 can include control system 109 having a network analyzer 110 that can analyze fluid provided to the PCB 102 and ones of the components 104-108. If contaminants are detected in fluid provided by the test system 100 to the PCB 102 and the components 104-108, the network analyzer 110 can determine a type of contaminant along with a concentration of the contaminant. The network analyzer 110 can be a fluid analyzer that can implement an ion chromatography system that can be used to determine contaminant type and contaminant concentration.

The test system 100 can also include an arm 112 that extends between the network analyzer 110 at a proximal end of the arm 112 and a snorkel 114 disposed at a distal end of the arm 112. The arm 112 can extend and retract in a horizontal direction as shown with bidirectional arrow X. Moreover, the arm 112 can extend and retract in a vertical direction as shown with bidirectional arrow Y. When the arm 112 moves along the horizontal and vertical directions, the snorkel 114 can also move along with the horizontal and vertical directions with the arm 112.

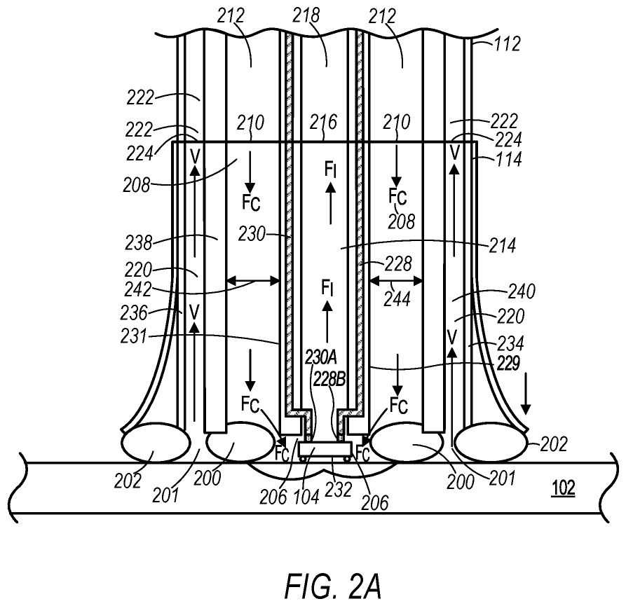

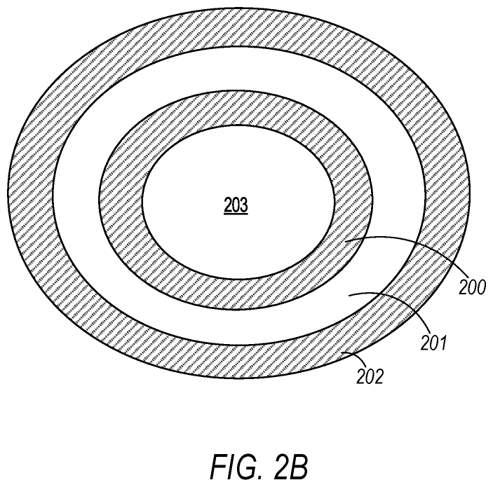

The snorkel 114 can be positioned over, and encase, any of the components 104-108, such as the component 104, in order to assist with the detection of contaminants and the electrical properties of the components 104-108. Making reference to FIG. 2, the snorkel 114 can include a flexible fluid seal 200 and a flexible vacuum seal 202 at a bottom portion of the snorkel 114. The flexible fluid seal 200 can form a seal with a surface 204 of the PCB 102 to sealingly engage therewith. As will be detailed further on, a seal formed between the flexible fluid seal 200 and the PCB surface 204 for sealing engagement therebetween can minimize the seepage of fluids F_{C} and F_{I} from a fluid channel 206.

The flexible vacuum seal 202 can also form a seal with the PCB surface 204 to sealingly engage therewith. When the flexible vacuum seal 202 forms a seal with the PCB surface 204, a vacuum, as shown with the arrows V, can be created with between the snorkel 114 and the PCB 102. The vacuum V can be created between the flexible fluid seal 200 and the flexible vacuum seal 202, as shown with respect to FIG. 2. The vacuum V, in conjunction with the vacuum seal 202, can create a vacuum boundary 201 (FIG. 2B) that can be disposed between the flexible fluid seal 200 and the flexible vacuum seal 202. In addition, a fluid boundary 203 (FIG. 2B) defined by the flexible fluid seal 200 can be disposed within the vacuum boundary 201. The vacuum V can be created to facilitate the formation of a seal between the flexible fluid seal 200 and the PCB surface 204. The vacuum V can also facilitate the formation of a seal between the flexible vacuum seal 202 and the PCB surface 204. Each of the flexible fluid seal 200 and the flexible vacuum seal 202 can be formed from any material that is flexible and easily deformable, examples can include rubber or the like.

The snorkel 114 can also include fluid inlet ports 208 that can be adjacent a distal end 210 of fluid inlets 212 that are disposed within the arm 112. The fluid inlets 212 can be operatively coupled with a fluid source 116 at the control system 109. The fluid source 116 can provide the fluid F_{C}, which can refer to clean fluid, such as fluid that does not include contaminants, to the fluid inlets 212. The fluid inlets 212 can then provide the fluid F_{C} from the fluid source 116 to the fluid inlet ports 208.

In order to allow for the evacuation of the fluid F_{I}, which can refer to dirty fluid, such as fluid that includes contaminants such as ionics, the snorkel 114 can have a fluid outlet port 214 adjacent a distal end 216 of a fluid outlet 218 that is disposed within the arm 212. The fluid outlet 218 can be operatively coupled with the network analyzer 110 along with a fluid pump that can operate to evacuate the fluid F_{I} via the fluid outlet 218 provided by the fluid source 116 and the fluid inlets 212. The fluid inlet ports 208 along with the fluid outlet port 214 can define the fluid channel 206. The flexible fluid seal 200 can define the fluid boundary 203 that is created by the flexible fluid seal 200, the fluid channel 206, the fluid inlet ports 208, and the fluid outlet port 214.

The snorkel 114 can also have vacuum ports 220 that can be coupled to vacuum inlets 222 at a distal end 224 disposed within the arm 112. The vacuum inlets 222 can be operatively coupled with a vacuum source 118 located at the control system 109. The vacuum source 118 can function to create the vacuum boundary 201. When the vacuum V is applied, the flexible fluid seal 200 and the flexible vacuum seal 202 can be biased against the PCB surface 204, thereby creating a seal between the PCB surface 204 and the flexible fluid seal 200. Furthermore, when the vacuum V is applied, the flexible vacuum seal 202 can be biased against the PCB surface 204 thereby creating a seal between the PCB surface 204 and the vacuum fluid seal 202 along with creating the vacuum boundary 201.

In addition to the vacuum ports 220, the snorkel 114 can also include electrodes 228 and 230 disposed in ribs 229 and 231. The electrodes 228 and 230 can extend from the control system 109 through the arm 112, and into the snorkel 114. One of the electrodes 228 and 230 can be a cathode and the other of the electrodes 228 and 230 can be an anode. A tip 228A of the electrode 228 can extend into the fluid channel 206. In addition, a tip 230A of the electrode 230 can also extend into the fluid channel 206.

When the fluid inlet ports 208 provide the fluid F_{C}, the fluid channel 206 can be provided, where the component 104 can be disposed within the fluid channel 206. As the fluid F_{C} passes over the component 104 and under the component 104 at a component underside 232, the fluid F_{C} can become dirty with contaminants present at the component 104, on the PCB surface 204, and at areas surrounding the component 104. When the fluid F_{C} becomes dirty, the fluid F_{C} can become the fluid F_{I}.

The presence of contaminants in the fluid F_{I} can be determined by a resistance that is measured across the electrode tips 228A and 230A when a voltage is applied to the electrodes 228 and 230. In particular, ionics in the fluid F_{I} can decrease a resistance across the electrode tips 228A and 230A. The decrease in the resistance can be determined at the control system 109, which can be configured to measure the resistance across the electrode tips 228A and 230A.

The control system 109 can have a preset resistance against which the measured resistance across the electrode tips 228A and 230A is compared, such as 18 megaohms, where a resistance measured above the preset resistance can correlate to the fluid having no contaminants, i.e., the fluid traveling into the fluid outlet port 214 and into the fluid outlet 218 is the fluid F_{C}. However, if the control system 109 measures a resistance across the electrode tips 228A and 230A that is less than the preset resistance, such as below 18 megaohms, then this can indicate that the fluid has contaminants. Thus, instead of being the fluid F_{C}, the fluid traveling into the fluid outlet port 214 and into the fluid outlet 218 is the fluid F_{I}.

In scenarios where the fluid traveling into the fluid outlet port 214 and into the fluid outlet 218 is the fluid F_{I}, this can be indicative of the component 104 and/or the PCB surface 204 having contaminants. When the measured resistance falls below the preset resistance, the network analyzer 110 can analyze the fluid to determine a concentration of contaminants in the fluid, such as by using ion chromatography techniques where the fluid outlet 218 can be coupled to the network analyzer 110 and the ion chromatography system to deliver the fluid F_{I} for analysis, as discussed above. In addition to determining if the component 104 and/or the PCB surface 204 is dirty, the measured resistance across the electrode tips 228A and 230A can be used to determine electrical characteristics of the component 104.

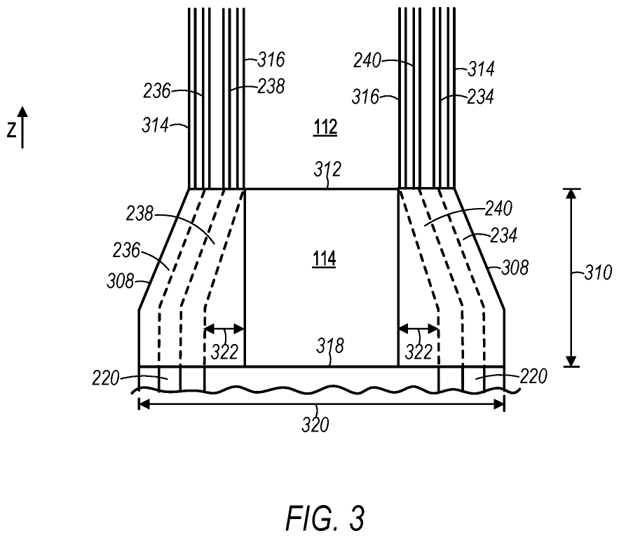

As noted above, the snorkel 114 can be adjusted to encase components, such as the components 104-108, that have different sizes and geometries, in order to minimize the possibility of the fluid from dispersing to other areas of the PCB 102 and other components on the PCB 102. In order to provide this functionality, the snorkel 114 can include the ribs 238 and 240 along with ribs 234 and 236 that can be enclosed by a housing 308 of the snorkel 114, as shown with reference to FIG. 3. The ribs 234-240 can be configured to move between contracted and expanded positions. The ribs 234-240 and the snorkel housing 308 can contract to multiple contracted positions and can expand to multiple expanded positions. The contracted and expanded positions can depend on the size and/or geometry of a component for which contaminant testing and electrical testing as discussed herein will be performed.

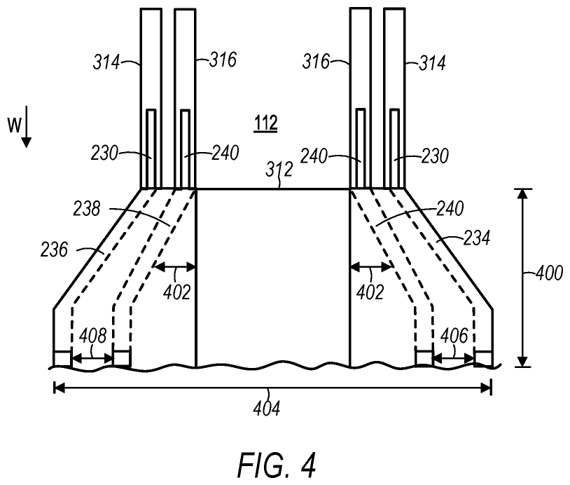

In order to facilitate expansion and contraction of the snorkel 114, the snorkel housing 308 can be formed of a material that allows for the repeated expansion and contraction of the snorkel housing 308 when the ribs 234-240 expand and contract as described herein. Examples of material that can be used can include rubber,? Elastic/flexible Polymers or Plastics, or the like. The ribs 234-240 can be formed from an elastomeric material or from shape memory material, such as Nitinol, where a natural position can be to have an expanded configuration as shown in FIG. 4. The ribs 234-240 can extend into the snorkel housing 308 from the arm 112. In particular, the ribs 234 and 236 can be disposed in passageways 314 of the arm 112. Moreover, the ribs 238 and 240 can be disposed in passageways 316 of the arm 112. The ribs 234-240 can be configured to slide within the arm passageways 314 and 316 such that the ribs slidingly couple with the arm passageways 314 and 316. Thus, the ribs 234-240 can slide into the arm 112 and slide out of the arm 112 via the passageways 314 and 316. The passageways 312 and 314 can have a straight configuration, which can straighten the ribs 234-240 as the ribs slide along a direction Z and further into the passageways 312 and 314.

In FIG. 3, the ribs 234-240 can move a distance 310 from a distal end 312 of the arm 112. The distance 310 can be defined between the arm distal end 312 and a distal end 318 of the snorkel 114. When the ribs 234-240 move along a direction Z and further into the arm passageways 314 and 316, the distance 310 decreases, i.e., the arm distal end 312 is closer to the snorkel distal end 318. Since the ribs 234-240 can be formed from a shape memory material, as the ribs 234-240 move further into the arm passageways 312 and 314 along the direction Z, the ribs 234-240 can become straighter, thereby causing a distance 320 of the snorkel 114 to be become smaller. Moreover, an angle 322 can be become smaller. Thus, between the ribs 234-240 becoming smaller and the angle 322 decreasing, a size of the snorkel 114, the ribs 234-240, and the snorkel housing 308 can contract.

The position shown with reference to FIG. 3 can be a contracted position of the snorkel 114. When the ribs 234-240 are moved along a direction W, the snorkel 114 can have an expanded position, as shown with reference to FIG. 4. When the ribs 234-240 are formed from a shape memory material having a naturally expanded position, as a greater portion of the ribs 234-240 move out of the arm passageways 314 and 316, the arm distal end 312 can move further away from the snorkel distal end 318, thereby increasing the distance 310 to a distance 400. By virtue of having the naturally expanded position, the angle 322 can increase to an angle 402 as the distance between the arm distal end 312 and the snorkel distal end 318 increases such that the snorkel distance 320 can increase to a distance 404. Here, the distance 404 can be greater than the distance 320 such that the snorkel 115 can have an expanded position to encase components having a greater surface area in comparison to a surface area for components that can be enclosed by the snorkel 114 when the snorkel 114 is in the contracted position of FIG. 3. Furthermore, as the distance 320 increases to the distance 404, a distance 406 between the rib 236 and the rib 240 and a distance 408 between the rib 236 and the rib 238 can both increase. Furthermore, the snorkel housing 308 can expand when the ribs 234-240 have the configuration in FIG. 4 and can contract when the ribs 234-240 have the configuration in FIG. 3. Thus, the ribs 234-240 can be movable between first and second positions defined by the distances 310 and 400.

By virtue of being flexible, each of the flexible fluid seal 200 and the flexible vacuum seal 202 can expand when the distance 320 of the snorkel 114 changes to the distance 404. Moreover, by virtue of being flexible, each of the flexible fluid seal 200 and the flexible vacuum seal 202 can contract when the distance 404 of the snorkel 114 changes to the distance 320. Thus, regardless of the snorkel 114 being extended the distances 320 or 404 or anything greater than or less than both of these distance, the snorkel 114 can maintain the vacuum boundary 201 and the fluid boundary 203 in either configuration.

As the ribs 234-240, and in particular the ribs 238 and 240, move along the directions W and Z and increase or decrease in width relative to the snorkel 114, the electrodes 228 and 230 along with the electrode tips 228A and 230A can also be adjusted. Thus, the electrodes 228 and 230 along with the electrode tips 228A and 230A can be adjusted based on the dimensions of the components 104-108.

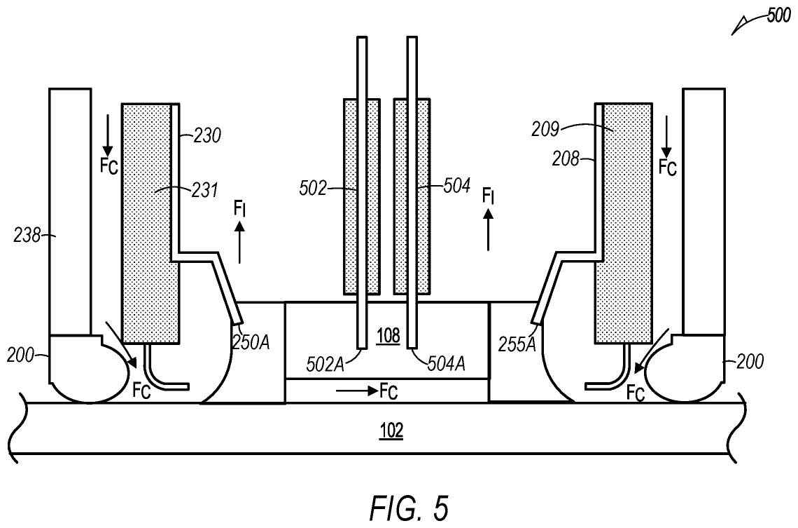

As indicated above, the test system 100 can also be used to test electrical characteristics of the components 104-108. Now making reference to FIG. 5, a snorkel 500 is shown. The snorkel 500 can couple with the arm 112 as discussed above with reference to FIGS. 1-4. In addition to the electrodes 228 and 230, the snorkel 500 can include electrodes 502 and 504 having tips 502A and 504A. The electrodes 228, 230, 502, and 504 and the electrode tips 228A, 230A, 502A, and 504A can provide the snorkel 500 with a four tip electrode, which can be used to measure resistance along with measuring electrical characteristics of the components 104-108.

The electrode tips 228A, 230A, 502A, and 504A can be used to monitor electrical resistance between conductors on the components 104-108 when a voltage is applied to the electrodes 228, 230, 502, and 504 and the electrode tips 228A, 230A, 502A, and 504A. The electrodes 228, 230, 502, and 504 and the electrode tips 228A, 230A, 502A, and 504A can be configurable to match dimensions of any of the components 104-108. More specifically, since the electrodes 228 and 230 along with the electrode tips 228A and 230A are adjustable via the ribs 238 and 240 as discussed above, the electrodes 228 and 230 along with the electrode tips 228A and 230A can be adjustable based on the dimensions of the components 104-108.

When the electrodes 228 and 230 along with the electrode tips 228A and 230A are adjusted, the electrodes 228, 230, 502, and 504, via the electrode tips 228A, 230A, 502A, and 504A, can measure localized resistance drops when a voltage is applied. The measured electrical resistance can be tied to performance of an integrated circuit that implements the components 104-108. Thus, electrical resistance can be tested on a component-by-component basis, which can be tied to overall integrated circuit performance. Since the electrodes 228, 230, 502, and 504, and the electrode tips 228A, 230A, 502A, and 504A, are adjustable, the snorkel 500 can be used to measure electrical components of the integrated circuit having different dimensions.

The snorkel 500 can also be used to determine the presence of contaminants at the component 108 and the PCB surface 204 by measuring the resistance of the fluid F_{C} that is delivered to the component as discussed above with reference to FIGS. 1-4. Moreover, if contaminants are at the component 108 and/or the PCB surface 104 such that the fluid F_{I} is created, the fluid F_{I} can be tested as discussed above to determine contaminant type and contaminant concentration. In particular, the fluid F_{C} can travel underneath the component 108 adjacent an underside 506 of the component 108 as discussed above with reference to FIG. 2.

### ADDITIONAL EXAMPLES

Example 1 is a system for determining a presence of contaminants and electrical properties of a component on a printed circuit board (PCB), the system comprising: an arm, the arm including: a fluid inlet operatively coupled with a fluid source; a fluid outlet operatively coupled with a fluid analyzer; first and second vacuum inlets, the first and second vacuum inlets being operatively coupled with a vacuum source; a snorkel coupled with the arm, the snorkel including: a flexible housing having a plurality of ribs, each rib of the plurality of ribs being configured to move between a first position and a second position; a fluid inlet port adjacent a distal end of the fluid inlet; a fluid outlet port adjacent a distal end of the fluid outlet; a first flexible seal defining a fluid boundary, wherein the fluid inlet port and the fluid outlet port define a fluid channel within the fluid boundary; a second flexible seal defining a vacuum boundary, wherein the first flexible seal is disposed within the vacuum boundary such that the fluid boundary is disposed within the vacuum boundary; and a plurality of electrical probes, wherein a tip of each electrical probe of the plurality of electrical probes is disposed within the fluid channel and at least one of the electrical probes of the plurality of electrical probes is adjustable, wherein the tips of each electrical probes are used to determine a resistance in fluid within the fluid channel, the resistance correlating to the presence of contaminants.

In Example 2, the subject matter of Example 1 includes, wherein the plurality of ribs extends from the arm and are a first distance from the arm in the first position.

In Example 3, the subject matter of Example 2 includes, wherein the plurality of ribs is a second distance from the arm in the second position, the second distance being shorter than the first distance.

In Example 4, the subject matter of Example 3 includes, wherein the plurality of ribs slidingly couple with the arm such that the plurality of ribs slides away from the arm in the first position and slide into the arm in the second position.

In Example 5, the subject matter of Examples 3-4 includes, wherein the first flexible seal and the second flexible seal is expandable between the first position and second position of the plurality of ribs.

In Example 6, the subject matter of Examples 1-5 includes, wherein the vacuum boundary is disposed between the first flexible seal and the second flexible seal.

In Example 7, the subject matter of Examples 1-6 includes, wherein the flexible housing is formed of rubber extending between each rib of the plurality of ribs where the flexible housing expands when the plurality of ribs is in the first position.

In Example 8, the subject matter of Example 7 includes, wherein the flexible housing contracts into the second position when the plurality of ribs is in the second position.

In Example 9, the subject matter of Examples 1-8 includes, the fluid analyzer being an ion chromatography system, wherein the fluid outlet is coupled to the ion chromatography system where the ion chromatography system analyzes fluid provided from the fluid outlet.

In Example 10, the subject matter of Examples 1-9 includes, wherein the plurality of electrical probes includes a cathode and an anode and the plurality of electrical probes are configured to measure of a resistance of a fluid within the fluid channel.

Example 11 is a system for determining a presence of contaminants and electrical properties of a component on a printed circuit board (PCB), the system comprising: a fluid inlet operatively coupled with a fluid source; a fluid outlet operatively coupled with a fluid analyzer; first and second vacuum inlets, the first and second vacuum inlets being operatively coupled with a vacuum source; a snorkel comprising: a flexible housing having a plurality of ribs, each rib of the plurality of ribs being configured to move between a first position and a second position; a fluid inlet port adjacent a distal end of the fluid inlet; a fluid outlet port adjacent the fluid outlet; a first flexible seal defining a fluid boundary, wherein the fluid inlet port and the fluid outlet port define a fluid channel within the fluid boundary; a second flexible seal defining a vacuum boundary, wherein the first flexible seal is disposed within the vacuum boundary such that the fluid boundary is disposed within the vacuum boundary; and a plurality of electrical probes, wherein a tip of each electrical probe of the plurality of electrical probes is disposed within the fluid channel and at least one of the electrical probes of the plurality of electrical probes is adjustable, wherein the tips of each electrical probes are used to determine a resistance in fluid within the fluid channel, the resistance correlating to the presence of contaminants.

In Example 12, the subject matter of Example 11 includes, the system further comprising an arm where the plurality of ribs extends from the arm and are a first distance from the arm in the first position.

In Example 13, the subject matter of Example 12 includes, wherein the plurality of ribs is a second distance from the arm in the second position, the second distance being shorter than the first distance.

In Example 14, the subject matter of Example 13 includes, wherein the plurality of ribs slidingly couple with the arm such that the plurality of ribs slide out of the arm in the first position and slide into the arm in the second position and the first flexible seal and the second flexible seal is expandable between the first position and second position of the plurality of ribs.

In Example 15, the subject matter of Examples 11-14 includes, wherein the vacuum boundary is disposed between the first flexible seal and the second flexible seal.

In Example 16, the subject matter of Examples 11-15 includes, wherein the flexible housing is formed of rubber extending between each rib of the plurality of ribs where the flexible housing expands when the plurality of ribs is in the first position.

In Example 17, the subject matter of Examples 11-16 includes, wherein the plurality of electrical probes includes a cathode and an anode and the plurality of electrical probes are configured to measure of a resistance of a fluid within the fluid channel.

Example 18 is a snorkel for determining a presence of contaminants and electrical properties of a component on a printed circuit board (PCB), the snorkel comprising: a flexible housing having a plurality of ribs, each rib of the plurality of ribs being configured to move between a first position and a second position; a fluid inlet port; a fluid outlet port; a first flexible seal defining a fluid boundary, wherein the fluid inlet port and the fluid outlet port define a fluid channel within the fluid boundary; a second flexible seal defining a vacuum boundary, wherein the first flexible seal is disposed within the vacuum boundary such that the fluid boundary is disposed within the vacuum boundary; and a plurality of electrical probes, wherein a tip of each electrical probe of the plurality of electrical probes is disposed within the fluid channel, wherein the tips of each electrical probes are used to determine a resistance in fluid within the fluid channel, the resistance correlating to the presence of contaminants.

In Example 19, the subject matter of Example 18 includes, the snorkel being part of a system having an arm where the plurality of ribs extends from the arm and are a first distance from the arm in the first position.

In Example 20, the subject matter of Example 19 includes, wherein the plurality of ribs is a second distance from the arm in the second position, the second distance being shorter than the first distance and the plurality of ribs slidingly couple with the arm such that the plurality of ribs slide out of the arm in the first position and slide into the arm in the second position and the first flexible seal and the second flexible seal is expandable between the first position and second position of the plurality of ribs.

Example 21 is a system to implement of any of Examples 1-20.

Although teachings have been described with reference to specific example teachings, it will be evident that various modifications and changes may be made to these teachings without departing from the broader spirit and scope of the teachings. Accordingly, the specification and drawings are to be regarded in an illustrative rather than a restrictive sense. The accompanying drawings that form a part hereof, show by way of illustration, and not of limitation, specific teachings in which the subject matter may be practiced. The teachings illustrated are described in sufficient detail to enable those skilled in the art to practice the teachings disclosed herein. Other teachings may be utilized and derived therefrom, such that structural and logical substitutions and changes may be made without departing from the scope of this disclosure. This Detailed Description, therefore, is not to be taken in a limiting sense, and the scope of various teachings is defined only by the appended claims, along with the full range of equivalents to which such claims are entitled.

What is claimed is:

1. A system for determining a presence of contaminants and electrical properties of a component on a printed circuit board (PCB), the system comprising:
an arm, the arm including:
a fluid inlet operatively coupled with a fluid source;
a fluid outlet operatively coupled with a fluid analyzer;
first and second vacuum inlets, the first and second vacuum inlets being operatively coupled with a vacuum source;
a snorkel coupled with the arm, the snorkel including:
a flexible housing having a plurality of ribs, each rib of the plurality of ribs being configured to move between a first position and a second position;
a fluid inlet port adjacent a distal end of the fluid inlet;
a fluid outlet port adjacent a distal end of the fluid outlet;
a first flexible seal defining a fluid boundary, wherein the fluid inlet port and the fluid outlet port define a fluid channel within the fluid boundary;
a second flexible seal defining a vacuum boundary, wherein the first flexible seal is disposed within the vacuum boundary such that the fluid boundary is disposed within the vacuum boundary; and
a plurality of electrical probes, wherein a tip of each electrical probe of the plurality of electrical probes is disposed within the fluid channel and at least one of the electrical probes of the plurality of electrical probes is adjustable, wherein the tips of each electrical probes are used to determine a resistance in fluid within the fluid channel, the resistance correlating to the presence of contaminants.

2. The system of claim 1, wherein the plurality of ribs extends from the arm and are a first distance from the arm in the first position.

3. The system of claim 2, wherein the plurality of ribs is a second distance from the arm in the second position, the second distance being shorter than the first distance.

4. The system of claim 3, wherein the plurality of ribs slidingly couple with the arm such that the plurality of ribs slides away from the arm in the first position and slide into the arm in the second position.

5. The system of claim 3, wherein the first flexible seal and the second flexible seal is expandable between the first position and second position of the plurality of ribs.

6. The system of claim 1, wherein the vacuum boundary is disposed between the first flexible seal and the second flexible seal.

7. The system of claim 1, wherein the flexible housing is formed of rubber extending between each rib of the plurality of ribs where the flexible housing expands when the plurality of ribs is in the first position.

8. The system of claim 7, wherein the flexible housing contracts into the second position when the plurality of ribs is in the second position.

9. The system of claim 1, the fluid analyzer being an ion chromatography system, wherein the fluid outlet is coupled to the ion chromatography system where the ion chromatography system analyzes fluid provided from the fluid outlet.

10. The system of claim 1, wherein the plurality of electrical probes includes a cathode and an anode and the plurality of electrical probes are configured to measure of a resistance of a fluid within the fluid channel.

11. A system for determining a presence of contaminants and electrical properties of a component on a printed circuit board (PCB), the system comprising:
a fluid inlet operatively coupled with a fluid source;
a fluid outlet operatively coupled with a fluid analyzer;
first and second vacuum inlets, the first and second vacuum inlets being operatively coupled with a vacuum source;
a snorkel comprising:
a flexible housing having a plurality of ribs, each rib of the plurality of ribs being configured to move between a first position and a second position;
a fluid inlet port adjacent a distal end of the fluid inlet;
a fluid outlet port adjacent the fluid outlet;
a first flexible seal defining a fluid boundary, wherein the fluid inlet port and the fluid outlet port define a fluid channel within the fluid boundary;
a second flexible seal defining a vacuum boundary, wherein the first flexible seal is disposed within the vacuum boundary such that the fluid boundary is disposed within the vacuum boundary; and
a plurality of electrical probes, wherein a tip of each electrical probe of the plurality of electrical probes is disposed within the fluid channel and at least one of the electrical probes of the plurality of electrical probes is adjustable, wherein the tips of each electrical probes are used to determine a resistance in fluid within the fluid channel, the resistance correlating to the presence of contaminants.

12. The system of claim 11, the system further comprising an arm where the plurality of ribs extends from the arm and are a first distance from the arm in the first position.

13. The system of claim 12, wherein the plurality of ribs is a second distance from the arm in the second position, the second distance being shorter than the first distance.

14. The system of claim 13, wherein the plurality of ribs slidingly couple with the arm such that the plurality of ribs slide out of the arm in the first position and slide into the arm in the second position and the first flexible seal and the second flexible seal is expandable between the first position and second position of the plurality of ribs.

15. The system of claim 11, wherein the vacuum boundary is disposed between the first flexible seal and the second flexible seal.

16. The system of claim 11, wherein the flexible housing is formed of rubber extending between each rib of the plurality of ribs where the flexible housing expands when the plurality of ribs is in the first position.

17. The system of claim 11, wherein the plurality of electrical probes includes a cathode and an anode and the plurality of electrical probes are configured to measure of a resistance of a fluid within the fluid channel.

18. A snorkel for determining a presence of contaminants and electrical properties of a component on a printed circuit board (PCB), the snorkel comprising:
a flexible housing having a plurality of ribs, each rib of the plurality of ribs being configured to move between a first position and a second position;
a fluid inlet port;
a fluid outlet port;
a first flexible seal defining a fluid boundary, wherein the fluid inlet port and the fluid outlet port define a fluid channel within the fluid boundary;
a second flexible seal defining a vacuum boundary, wherein the first flexible seal is disposed within the vacuum boundary such that the fluid boundary is disposed within the vacuum boundary; and
a plurality of electrical probes, wherein a tip of each electrical probe of the plurality of electrical probes is disposed within the fluid channel, wherein the tips of each electrical probes are used to determine a resistance in fluid within the fluid channel, the resistance correlating to the presence of contaminants.

19. The snorkel of claim 18, the snorkel being part of a system having an arm where the plurality of ribs extends from the arm and are a first distance from the arm in the first position.

20. The snorkel of claim 19, wherein the plurality of ribs is a second distance from the arm in the second position, the second distance being shorter than the first distance and the plurality of ribs slidingly couple with the arm such that the plurality of ribs slide out of the arm in the first position and slide into the arm in the second position and the first flexible seal and the second flexible seal is expandable between the first position and second position of the plurality of ribs.
